(19) United States
(12) Patent Application Publication
(10) Pub. No.: US 2004/0139998 A1
(43) Pub. Date: Jul. 22, 2004

(54) Thermoelectric conversion device, thermoelectric conversion device unit, and method for manufacturing thermoelectric conversion device

(75) Inventors: Kouichi Itoigawa, Aichi (JP); Hiroshi Ueno, Aichi (JP); Susumu Sugiyama, Shiga-ken (JP); Toshiyuki Toriyama, Shiga-ken (JP)

Correspondence Address: CARSTENS YEE & CAHOON, LLP, P O BOX 802334, DALLAS, TX, 75380

(73) Assignees: KABUSHIKI KAISHA TOKAI RIKA DENKI SEISAKUSHO, Aichi (JP); THE RITSUMEIKAN TRUST, Kyoto (JP)

(21) Appl. No.: 10/746,990

(22) Filed: Dec. 24, 2003

(30) Foreign Application Priority Data
Dec. 24, 2002 (JP) 2002-372998

(51) Int. Cl. B23P 13/00; H01L 35/28

(52) U.S. Cl. 136/225; 29/2

(57) ABSTRACT

A thermoelectric conversion device that eliminates differences in the distance between two adjacent junctions. The thermoelectric conversion device includes an insulative core. A thermocouple assembly is formed spirally around the insulative core contacting the circumferential surface and includes a plurality of series-connected thermocouples. Each of the thermocouples defines a single loop of the spiral and has a first metal body, which is formed in half of the loop, and a second metal body, which is formed in the remaining half of the loop from a metal differing from the first metal body. A plurality of junctions are formed between the first metal body and the second metal body of each thermocouple. The junctions are formed at 180° intervals along the spiral thermocouple assembly.

### BACKGROUND OF THE INVENTION

The present invention relates to a thermoelectric conversion device that uses the Seebeck effect to generate electrical power from the temperature difference between a hot junction and a cold junction, a method for manufacturing such a thermoelectric conversion device, and a thermoelectric conversion device unit. A thermoelectric conversion device and a thermoelectric device unit are used as a main power supply or auxiliary power supply for an electronic device and as a temperature sensor or infrared sensor.

In the prior art, a thermoelectric conversion device that includes a thermocouple assembly formed from a plurality of series-connected thermocouples has been proposed. For example, Japanese Laid-Open Patent Publication No. 2002-50801 describes a first prior art example of a thermoelectric conversion device including a plurality of series-connected thermocouples. Each thermocouple is L-shaped and includes a parallel portion, which is parallel to a substrate, and a vertical portion, which is perpendicular to the substrate.

In the thermoelectric conversion device of Japanese Laid-Open Patent Publication No. 2002-50801, a plurality of thermocouples, each having a first junction and a second junction, are arranged on the substrate parallel to the substrate. The thermocouples are connected in series to one another to form a thermocouple assembly. Each thermocouple is bent orthogonally from the parallel portion (first junction portion) at a bent portion to form the vertical portion.

In the thermoelectric conversion device of Japanese Laid-Open Patent Publication No. 2002-50801, the angle between the parallel portion and the vertical portion at the bent portion is ninety degrees. A first junction is defined on the end of each parallel portion that is opposite to the bent portion. A second junction is defined on the end of each vertical portion that is opposite to the bent portion. This obtains a predetermined distance between the first junctions and the second junctions in a direction perpendicular to the substrate. Thus, the thermoelectric conversion device has satisfactory thermoelectric conversion efficiency.

However, in the thermoelectric conversion device of Japanese Laid-Open Patent Publication No. 2002-50801, when bending each thermocouple to form the parallel portion and the vertical portion, the vertical portions of the thermocouples may have different lengths. Thus, there is a shortcoming in that the distance between the first and second junctions may differ between the thermocouples.

Japanese Laid-Open Patent Publication No. 9-45967 describes a second prior art example of a thermoelectric device having a zigzagged thermocouple assembly. The thermocouple assembly includes a plurality of thermocouples formed by alternately welding first metal bodies and second metal bodies. The thermocouple assembly has a plurality of junctions formed between the first and second metal bodies. Among the junctions, every other one is referred to as a first junction and the remaining ones are referred to as a second junction.

However, in the thermoelectric conversion device of Japanese Laid-Open Patent Publication No. 9-45967, when the first metal bodies and the second metal bodies are not formed with accurate lengths or when the welding positions of the junctions are not accurate, the distance between the first and second junctions may differ between thermocouples.

### SUMMARY OF THE INVENTION

One aspect of the present invention is a thermoelectric conversion device including an insulative core having a circumferential surface. A thermocouple assembly is formed spirally around the insulative core contacting the circumferential surface and including a plurality of series-connected thermocouples. Each of the thermocouples defines a single loop of the spiral and has a first metal body, which is formed in half of the loop, and a second metal body, which is formed in the remaining half of the loop from a metal differing from the first metal body. A plurality of junctions are formed between the first metal body and the second metal body of each thermocouple. The junctions are formed at 180° intervals along the spiral thermocouple assembly.

Another aspect of the present invention is a thermoelectric conversion device unit including a thermoelectric conversion device provided with an insulative core having a circumferential surface. A thermocouple assembly is formed spirally around the insulative core contacting the circumferential surface and having a plurality of series-connected thermocouples. Each of the thermocouples defines a single loop of the spiral and has a first metal body, which is formed in half of the loop, and a second metal body, which is formed in the remaining half of the loop from a metal differing from the first metal body. A plurality of junctions are formed between the first metal body and the second metal body of each thermocouple. The junctions are formed at 180° intervals along the spiral thermocouple assembly. A heat absorber is connected to every other one of the junctions. A heat radiator is connected to the remaining ones of the junctions that are not connected to the heat absorber.

A further aspect of the present invention is a method for manufacturing a thermoelectric conversion device. The thermoelectric conversion device includes an insulative core having an axis and a circumferential surface. The method includes forming a first metal layer on half of the circumferential surface of the insulative core, forming a second metal layer on the remaining half of the circumferential surface of the insulative core from a metal that differs from that of the first metal layer, and removing part of the first metal layer and part of the second metal layer spirally along the axis of the insulative core.

A further aspect of the present invention is a method for manufacturing a thermoelectric conversion device. The thermoelectric conversion device includes an insulative core having an axis and a circumferential surface. The method includes forming a mask on the circumferential surface of the insulative core, forming a spiral exposed portion on the circumferential surface of the insulative core by removing part of the mask spirally along the axis of the insulative core, forming a first metal layer on half of the circumferential surface of the insulative core in the spiral exposed portion, forming a second metal layer on the remaining half of the circumferential surface of the insulative core from a metal that differs from that of the first metal layer in the spiral exposed portion, and removing the residual mask.

A further aspect of the present invention is a method for manufacturing a thermoelectric conversion device. The thermoelectric conversion device includes an insulative core having an axis and a circumferential surface. The method includes forming a first metal layer on half of the circumferential surface of the insulative core, forming a second metal layer on the remaining half of the circumferential surface of the insulative core from a metal that differs from that of the first metal layer, forming bounding junctions where the first metal layer and the second metal layer are bound to each other, and removing part of the first metal layer and part of the second metal layer spirally along the axis of the insulative core.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1A is a schematic plan view of a thermoelectric conversion device unit according to a first embodiment of the present invention;

FIG. 1B is a schematic front view showing the thermoelectric conversion device unit of FIG. 1A;

FIG. 2 is an enlarged schematic side view showing a thermoelectric conversion device included in the thermoelectric conversion device unit of FIG. 1A;

FIG. 3 is a schematic front view showing the thermoelectric conversion device of FIG. 2;

FIGS. 4 to 8 and FIG. 9A are partial cross-sectional side views showing manufacturing processes of the thermoelectric conversion device of FIG. 2;

FIG. 9B is a front view showing a manufacturing process of the thermoelectric conversion device of FIG. 2;

FIG. 10 is a partial cross-sectional view showing a manufacturing process of a thermoelectric conversion device according to a second embodiment of the present invention;

FIGS. 11 to 13 and FIG. 14A are partial cross-sectional side views showing manufacturing processes of the thermoelectric conversion device of FIG. 10;

FIG. 14B is a front view showing a manufacturing process of the thermoelectric conversion device of FIG. 10;

FIG. 15 is a schematic side view showing the thermoelectric conversion device in a curved state; and

FIG. 16 is a schematic front view showing the thermoelectric conversion device unit in a curved state.

### DETAILED DESCRIPTION OF THE PREFERRED EMBODIMENTS

In the drawings, like numerals are used for like elements throughout.

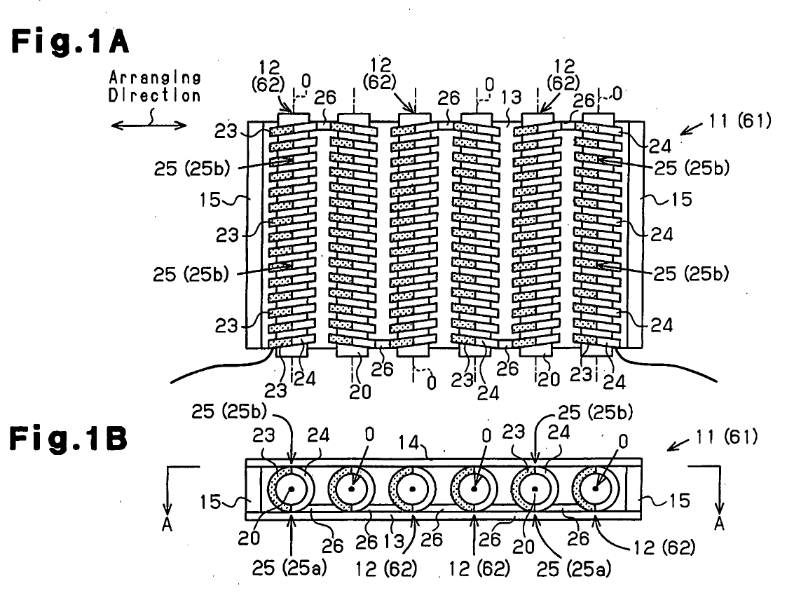

Referring to FIGS. 1A and 1B, a thermoelectric conversion device unit 11 according to a first embodiment of the present invention includes a plurality of thermoelectric conversion devices 12, a heat absorbing plate 13 serving as a heat absorber, a heat radiating plate 14 serving as a heat radiator, and spacers 15. The heat absorbing plate 13 is made of a flexible polyimide resin, which is mixed with a black body (e.g., cobalt oxide). The heat radiating plate 14 is made of flexible aluminum foils.

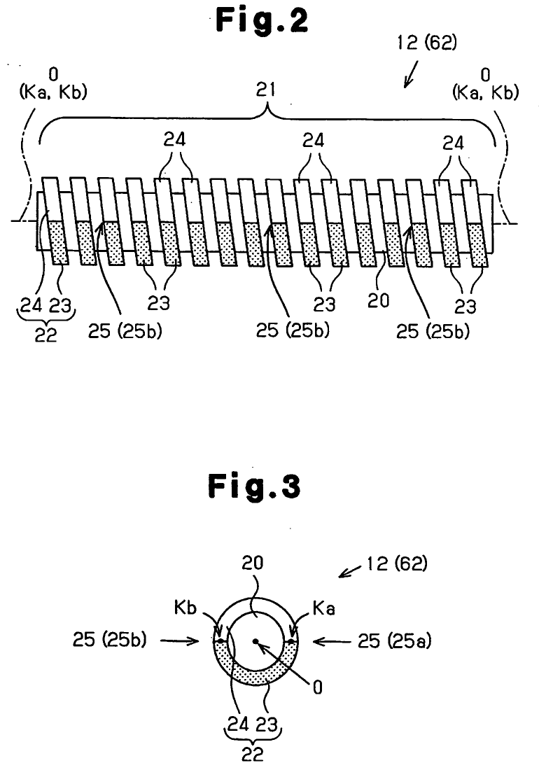

The thermoelectric conversion device 12 will now be discussed. Referring to FIGS. 2 and 3, the thermoelectric conversion device 12 includes rod-like cores 20 and a thermocouple assembly 21 extending spirally around the circumferential surface of each core 20. Each thermocouple assembly 21 is entirely in close contact with the circumferential surface of the core 20. Each core 20 is flexible and made of an insulative synthetic resin. The core 20 has a diameter of, for example, 5 mm. The diameter of the core 20, of which axis is denoted by the letter O, is uniform in the axial direction of the core 20.

The thermocouple assembly 21 includes a plurality of series-connected thermocouples 22. Each thermocouple 22 includes a first metal portion 23, which is formed from nickel (Ni), and a second metal portion 24, which is formed from chrome (Cr). The first metal portion 23 corresponds to a first metal body, and the second metal portion 24 corresponds to a second metal body. Accordingly, the thermocouple assembly 21 includes alternately connected first metal portions 23 and second metal portions 24. A plurality of junctions 25 are defined between the first metal portions 23 and the second metal portions 24. The junctions 25 are located at 180° intervals along the spiral thermocouple assembly 21.

Among the junctions 25, every other junction 25 is referred to as hot junctions 25a and the remaining junctions 25 are referred to as cold junctions 25b. A hypothetical line Ka that lies along the hot junctions 25a and a hypothetical line Kb that lies along the cold junctions 25b are parallel to the axis O. Accordingly, the hypothetical lines Ka and Kb are symmetric to each other about the axis O.

A thermoelectric conversion device unit 11 including a plurality of the thermoelectric conversion devices 12 will now be discussed. As shown in FIGS. 1A and 1B, a plurality of (in this embodiment, six) are arranged parallel to each other on the heat absorbing plate 13. The hot junctions 25a of the thermoelectric conversion devices 12 are adhered to the upper surface of the heat absorbing plate 13 to convey heat. A spacer 15 is fixed to each of the two ends of the heat absorbing plate 13 with respect to the arranging direction of the thermoelectric conversion device 12 (the lateral direction in FIG. 1A). The heat radiating plate 14 is fixed to the spacers 15 parallel to the heat absorbing plate 13. That is, the heat radiating plate 14 is fixed to the heat absorbing plate 13 by the spacers 15.

The cold junctions 25b of the thermoelectric conversion devices 12 are adhered to the heat radiating plate 14. The thermocouple assemblies 21 of the thermoelectric conversion devices 12 are connected in series to one another by wires 26.

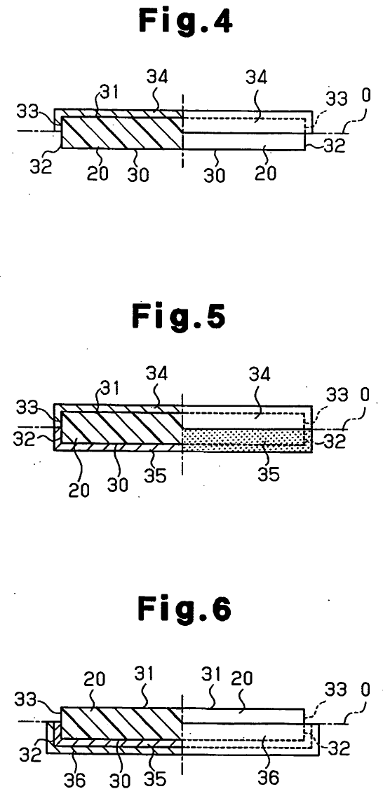

A method for manufacturing the thermoelectric conversion devices 12 of the first embodiment will now be discussed with reference to FIGS. 4 to 9B. FIGS. 4 to 8, FIG. 9A, FIGS. 10 to 13, and FIG. 14A show the left half of a core 20 as cross-sectional views and the right half of the core 20 as front views.

Half of the circumferential surface of the core 20 that is lower than the axis O as viewed in FIG. 4 is referred to as a first metal-covered surface 30. The remaining half of the circumferential surface of the core 20 that is higher than the axis as viewed in FIG. 4 is referred to as a second metal-covered surface 31. Each end of the core 20 has a first semicircular surface 32 corresponding to the first metal-covered surface 30 and defined under the axis O as viewed in FIG. 4 and a second semicircular surface 33 corresponding to the second metal-covered surface 31 above the axis O as viewed in FIG. 4.

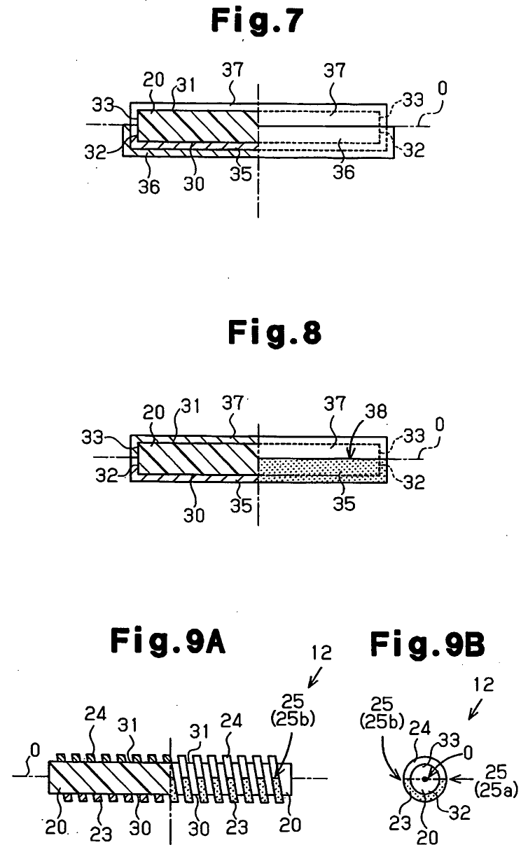

As shown in FIG. 4, a resist layer 34, which serves as a mask, is applied to the second metal-covered surface 31 and the second semicircular surface 33 of the core 20. Then, referring to FIG. 5, a dipping process is performed to apply a nickel (Ni) layer 35 to the first metal-covered surface 30 and the two first semicircular surfaces 32 of the core 20. Subsequently, a resist layer 36 is applied to the nickel layer 35. Further, referring to FIG. 7, a dipping process is performed to apply a chrome (Cr) layer 37 to the second metal-covered surface 31 and the two second semicircular surfaces 33 of the core 20. Afterwards, the resist layer 36 is removed as shown in the state of FIG. 8. This forms the nickel layer 35 and the chrome layer 37 on the circumferential surface of the core 20 with bounding junctions 38 defined between the nickel layer 35 and the chrome layer 37.

Subsequently, part of the nickel layer 35 and the chrome layer 37 shown in FIG. 8 is spirally removed about the axis O. For example, a general-purpose die is used to spirally remove part of the nickel layer 35 and the chrome layer 37. Referring to FIGS. 9A and 9B, the first metal portions 23 are formed by cutting out part of the nickel layer 35, and the second metal portions 24 are formed by cutting out part of the chrome layer 37. The junctions (hot junctions 25a and cold junctions 25b) are defined at the bounding junctions 38 between the first metal portions 23 and the second metal portions 24.

The thermoelectric conversion device 12 and the thermoelectric conversion device unit 11 of the first embodiment have the advantages described below.

(1) Each thermoelectric conversion device 12 includes the core 20 and the thermocouple assembly 21, which extends along the circumferential surface of the core 20. The thermocouple assembly 21 includes the alternately arranged first metal portions 23 and the second metal portions 24. The junctions 25 where the first metal portions 23 and the second metal portions 24 are joined are arranged at 180° intervals along the spiral thermocouple assembly 21. Accordingly, the distance between adjacent junctions 25 is uniform throughout the thermocouple assembly 21. In other words, the distance between the hot junction 25a and the cold junction 25b is always the same for every one of the thermocouples 22.

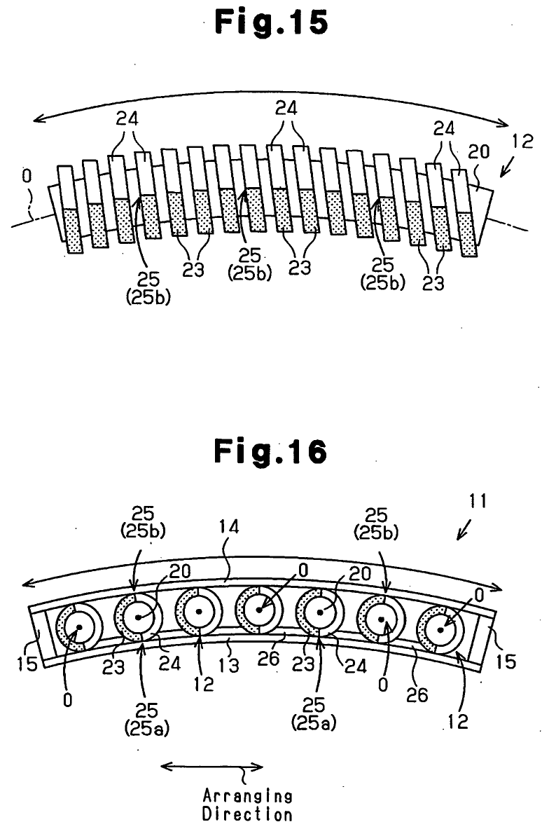

(2) The core 20 of the thermoelectric conversion device 12 is formed from a flexible synthetic resin. This enables the thermoelectric conversion device 12 to be curved (the axis O being curved) as shown in FIG. 15. Accordingly, all of the hot junctions 25a or all of the cold junctions 25b may be placed in contact with a curved surface. This increases the range of applications for the thermoelectric conversion device 12.

(3) The hot junctions 25a of each thermoelectric conversion device 12 are adhered to the heat absorbing plate 13, and the cold junctions 25b of each thermoelectric conversion device 12 are adhered to the heat radiating plate 14. Thus, in the thermoelectric conversion devices 12 of the thermoelectric conversion device unit 11, the hot junctions 25a efficiently absorb heat through the heat absorbing plate 13, and the cold junctions efficiently radiate heat through the heat radiating plate 14.

(4) The thermocouple assembly 21 of each thermoelectric conversion device 12 is formed by spirally cutting out the nickel layer 35 and the chrome layer 37 along the circumferential surface of the core 20. This eliminates differences in the distances between two adjacent junctions 25. Further, the formation of the thermocouple assembly 21 is facilitated in comparison with the thermoelectric conversion device of Japanese Laid-Open Patent Publication Nos. 2002-50801 and 9-45967.

(5) A masking process, a resist process, and a dipping process are performed on the circumferential surface of the core 20 to form the thermocouple assembly 21 of each thermoelectric conversion device 12. This facilitates the manufacturing of the thermoelectric conversion device 12 in comparison to when manufacturing the thermoelectric conversion device with a large semiconductor manufacturing apparatus.

(6) The thermoelectric conversion device unit 11 includes the thermoelectric conversion devices 12 having the flexible cores 20, the flexible heat absorbing plate 13, and the flexible heat radiating plate 14. This keeps the hot junctions 25a and the cold junctions 25b in contact with the heat absorbing plate 13 and the heat radiating plate 14 even when the heat absorbing plate 13 and the heat radiating plate 14 are flexed. As a result, the thermoelectric conversion device unit 11 may be curved in the arranging direction of the thermoelectric conversion device units 11 (the lateral direction in FIG. 16). This enables the thermoelectric conversion device units 11 to be installed at curved locations without producing any gaps and increases the range of applications for the thermoelectric conversion devices 12. (The thermoelectric conversion device of Japanese Laid-Open Patent Publication No. 2002-50801 is formed on a silicon substrate and is thus not flexible).

(7) The core of each thermoelectric conversion device 12 is rod-like, and the thermocouple assembly 21 is formed along the circumferential surface of the core 20. In other words, each thermocouple 22 of the thermocouple assembly 21 is arcuate and does not have any edges. Thus, stress is not concentrated at any portion of the thermocouple 22 and line breakage does not occur even when stress is applied to each thermocouple 22 due to, for example, temperature fluctuation. (The thermoelectric conversion device of Japanese Laid-Open Patent Publication No. 2002-50801 has edges at the bent portions at which stress tends to be concentrated.)

A thermoelectric conversion device 62 and a thermoelectric conversion device unit 61 according to a second embodiment of the present invention will now be discussed with reference to FIGS. 10 to 14. The thermoelectric conversion device unit 61 has substantially the same structure as the thermoelectric conversion device unit 11 of the first embodiment. The thermoelectric conversion device 62 of the thermoelectric conversion device 62 is manufactured differently from the thermoelectric conversion device 12 of the first embodiment.

The manufacturing of the thermoelectric conversion device 62 of the second embodiment (refer to FIGS. 1A and 1B) will now be discussed with reference to FIGS. 10 to 14. FIGS. 10 to 13 and 14A show the left half of the core 20 as cross-sectional views and the right half of the core 20 as front views.

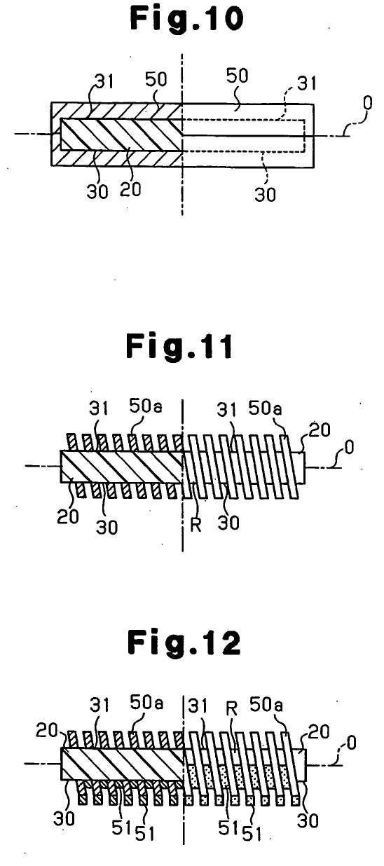

Referring to FIG. 10, a resist layer 50, which serves as a mask, is formed on the circumferential surface and end surfaces of the core 20. Referring to FIG. 11, an etching process is performed to eliminate unnecessary portions from the resist layer 50 and form a spiral resist 50a on the circumferential surface of the core 20 as shown in FIG. 11. This forms a spiral exposed portion R, which is not covered by the spiral resist 50a, on the circumferential surface of the core 20.

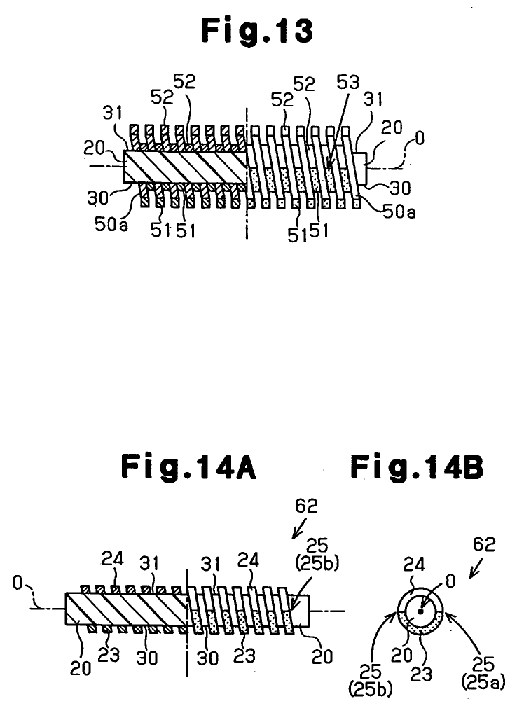

Referring to FIG. 12, physical deposition, such as sputtering (alternatively, vacuum deposition), is performed to apply a nickel (Ni) layer 51 to the exposed portion R and the spiral resist 50a on the half of the core 20 where the first metal-covered surface 30 is defined. Then, referring to FIG. 13, for example, sputtering (alternatively, vacuum deposition) is performed to apply a chrome (Ni) layer 52 to the exposed portion R and the spiral resist 50a on the half of the core 20 where the second metal-covered surface 31 is defined. This forms bounding junctions 53 defined between the nickel layer 51 and the chrome layer 52 on the circumferential surface of the core 20.

Subsequently, referring to FIGS. 14A and 14B, the spiral resist 50a and the nickel layer 51 and chrome layer 52 formed on the spiral resist 50a are removed. This leaves only the nickel layer 51 and the chrome layer 52 formed in correspondence with the exposed portion R on the circumferential surface of the core 20. The residual nickel layer 51 defines the first metal portion 23, and the residual chrome layer 52 defines the second metal portion 24.

The thermoelectric conversion device 62 and the thermoelectric conversion device unit 61 of the second embodiment have the same advantages as the first embodiment.

It should be apparent to those skilled in the art that the present invention may be embodied in many other specific forms without departing from the spirit or scope of the invention. Particularly, it should be understood that the present invention may be embodied in the following forms.

In each of the above embodiments, the diameter of the core 20 is not limited. Further, the core 20 may have the shape of a cylindrical pipe. The core 20 may have a polygonal or elliptical cross-section. Alternatively, the core 20 may be a pipe having a polygonal or elliptical cross-section.

In each of the above embodiments, the thermoelectric conversion device units 11 and 16 may respectively include just one thermoelectric conversion device 12 and 62.

In each of the above embodiments, the heat radiating plate 14 may be formed from an insulative resin with a metal film applied to the surface of the heat radiating plate 14.

In each of the above embodiments, the first metal portion 23 may be formed from gold (Au), and the second metal portion 24 may be formed from platinum (Pt). Further, the first metal portion 23 and the second metal portion 24 may be formed by any metal as long as they use different metals that enable thermoelectric conversion.

In each of the above embodiments, the core 20 may be formed to be insulative only at portions that contact the first metal portion 23 and the second metal portion 24. For example, the core 20 may be insulative only at the circumferential surface. In this specification, an insulative core refers to a core that is insulative at least at portions contacting the first and second metal portions.

In the first embodiment, the chrome layer 37 may be formed before the nickel layer 35 on the circumferential surface of the core 20.

In each of the above embodiments, the core 20 does not have to be flexible. Since the thermocouple assembly 21 is entirely supported by the core 20, the thermocouple assembly 21 is not deformed unless an external force equal to the sum of the external force resisting capacity of the thermocouple assembly 21 and the external force resisting capacity of the core 20 is applied to the thermocouple assembly 21. The thermocouple assemblies described in Japanese Laid-Open Patent Publications 2002-50801 and 9-45967 have no such supporting structure. Thus, these thermocouple assemblies are deformed when an external force that is greater than the resisting capacity of the thermocouple assembly is applied. Accordingly, the thermocouple assembly 21 resists deformation at a higher level in comparison to the thermocouple assemblies described in Japanese Laid-Open Patent Publications 2002-50801 and 9-45967.

In the first embodiment, an aluminum layer may be formed in lieu of the resist layer 34.

In the first embodiment, a general-purpose lathe may be used to remove part of the nickel layer 35 and the chrome layer 37 and form the spiral thermocouple assembly 21.

In the first embodiment, instead of forming the resist layer 34 on the first metal-covered surface 30 and the first semicircular surface 32, sputtering or vacuum deposition may be performed to form the nickel layer 35. In the same manner, sputtering or vacuum deposition may be performed to form the chrome layer 37 on the second metal-covered surface 31 and the second semicircular surface 33.

The present examples and embodiments are to be considered as illustrative and not restrictive, and the invention is not to be limited to the details given herein, but may be modified within the scope and equivalence of the appended claims.

What is claimed is:

1. A thermoelectric conversion device comprising:
an insulative core having a circumferential surface;
a thermocouple assembly formed spirally around the insulative core contacting the circumferential surface and including a plurality of series-connected thermocouples, wherein each of the thermocouples defines a single loop of the spiral and has a first metal body, which is formed in half of the loop, and a second metal body, which is formed in the remaining half of the loop from a metal differing from the first metal body; and
a plurality of junctions formed between the first metal body and the second metal body of each thermocouple, the junctions being formed at 180° intervals along the spiral thermocouple assembly.

2. The thermoelectric conversion device according to claim 1, wherein the insulative core is flexible.

3. The thermoelectric conversion device according to claim 1, wherein the insulative core is insulative at least at portions contacting the first metal body and the second metal body of each thermocouple.

4. The thermoelectric conversion device according to claim 1, wherein the insulative core is rod-like and has a circular cross-section.

5. A thermoelectric conversion device unit comprising:
a thermoelectric conversion device including:
an insulative core having a circumferential surface;
a thermocouple assembly formed spirally around the insulative core contacting the circumferential surface and having a plurality of series-connected thermocouples, wherein each of the thermocouples defines a single loop of the spiral and has a first metal body, which is formed in half of the loop, and a second metal body, which is formed in the remaining half of the loop from a metal differing from the first metal body; and
a plurality of junctions formed between the first metal body and the second metal body of each thermocouple, the junctions being formed at 180° intervals along the spiral thermocouple assembly;
a heat absorber connected to every other one of the junctions; and
a heat radiator connected to the remaining ones of the junctions that are not connected to the heat absorber.

6. The thermoelectric conversion device unit according to claim 5, wherein the insulative core is flexible.

7. The thermoelectric conversion device unit according to claim 5, wherein the insulative core is rod-like and has a circular cross-section.

8. The thermoelectric conversion device unit according to claim 5, wherein at least one of the heat absorber and the heat radiator is flexible.

9. The thermoelectric conversion device unit according to claim 5, further comprising:
a spacer arranged between the heat absorber and the heat radiator and fixed to at least one of the heat absorber and the heat radiator.

10. The thermoelectric conversion device unit according to claim 5, wherein the thermoelectric conversion device is one of a plurality of series-connected thermoelectric conversion devices.

11. A method for manufacturing a thermoelectric conversion device, the thermoelectric conversion device including an insulative core having an axis and a circumferential surface, the method comprising:
forming a first metal layer on half of the circumferential surface of the insulative core;
forming a second metal layer on the remaining half of the circumferential surface of the insulative core from a metal that differs from that of the first metal layer; and
removing part of the first metal layer and part of the second metal layer spirally along the axis of the insulative core.

12. The method for manufacturing a thermoelectric conversion device according to claim 11, wherein said forming a first metal layer and said forming a second layer include forming the first metal layer and the second metal layer by performing a dipping process.

13. The method for manufacturing a thermoelectric conversion device according to claim 11, wherein said forming a first metal layer and said forming a second layer include forming the first metal layer and the second metal layer by performing physical deposition.

14. The method for manufacturing a thermoelectric conversion device according to claim 11, wherein said removing includes spirally cutting out part of the first metal layer and part of the second metal layer spirally along the axis of the insulative core.

15. The method for manufacturing a thermoelectric conversion device according to claim 11, wherein the insulative core is flexible.

16. The method for manufacturing a thermoelectric conversion device according to claim 11, wherein the insulative core is rod-like and has a circular cross-section.

17. A method for manufacturing a thermoelectric conversion device, the thermoelectric conversion device including an insulative core having an axis and a circumferential surface, the method comprising:
forming a mask on the circumferential surface of the insulative core;
forming a spiral exposed portion on the circumferential surface of the insulative core by removing part of the mask spirally along the axis of the insulative core;
forming a first metal layer on half of the circumferential surface of the insulative core in the spiral exposed portion;
forming a second metal layer on the remaining half of the circumferential surface of the insulative core from a metal that differs from that of the first metal layer in the spiral exposed portion; and
removing the residual mask.

18. The method for manufacturing a thermoelectric conversion device according to claim 17, wherein said forming a spiral exposed portion includes spirally cutting out part of the mask along the axis of the insulative core.

19. The method for manufacturing a thermoelectric conversion device according to claim 17, wherein the insulative core is flexible.

20. A method for manufacturing a thermoelectric conversion device, the thermoelectric conversion device including an insulative core having an axis and a circumferential surface, the method comprising:
forming a first metal layer on half of the circumferential surface of the insulative core;
forming a second metal layer on the remaining half of the circumferential surface of the insulative core from a metal that differs from that of the first metal layer;
forming bounding junctions where the first metal layer and the second metal layer are bound to each other; and
removing part of the first metal layer and part of the second metal layer spirally along the axis of the insulative core.
